(19) United States
(12) Patent Application Publication
(10) Pub. No.: US 2003/0176073 A1
(43) Pub. Date: Sep. 18, 2003

(54) Plasma etching of Ir and PZT using a hard mask and C12/N2/O2 and C12/CHF3/O2 chemistry

(76) Inventors: Chentsau Ying, Cupertino, CA (US); Tomoyuki Sakoda, Yamanashi (JP); Chiu Chi, San Jose, CA (US)

Correspondence Address: A GILENT TECHNOLOGIES, INC., Legal Department, DL429, Intellectual Property Administration, P.O. Box 7599, Loveland, CO, 80537-0599, US

(21) Appl. No.: 10/096,733

(22) Filed: Mar. 12, 2002

(51) Int. Cl. H01L 21/302; H01L 21/461

(52) U.S. Cl. 438/710

(57) ABSTRACT

Processes for etching PZT and/or forming a ferroelectric capacitor with Ir/IrOx electrodes and a PZT ferroelectric layer use a titanium-containing hard mask, a chlorine/oxygen-based plasma, and a hot substrate, typically at about 350 ° C. The processes add a fluorine-containing compound such as CHF₃ to the chlorine/oxygen-based plasma for etching of the PZT layer and add nitrogen to improve sidewall profiles when etching Ir layers. The chlorine/oxygen-based plasmas provide good selectivity with high etch rates for Ir and PZT layers and low etch rates for the hard mask.

### BACKGROUND

A ferroelectric random access memory (FeRAM) is a non-volatile memory that uses the persistent electric fields in a ferroelectric material to store data. FIG. 1 illustrates a typical FeRAM cell 100, which includes a ferroelectric capacitor having a top electrode 110, a ferroelectric layer 120, and a bottom electrode 130 formed overlying a semiconductor substrate 140. Generally, circuit elements (not shown) in substrate 140 and in structure overlying FeRAM cell 100 enable writing data to and reading data from FeRAM cell 100.

An operation writing to FeRAM cell 100 applies write voltages to top and bottom electrodes 110 and 130. The write voltages, which are set according to the data value being written, charge electrodes 110 and 130 and polarize ferroelectric layer 120. After the write voltages are removed, persistent polarizations remain in ferroelectric layer 120 and indicate the data value associated with the previously applied write voltage. A read operation senses a voltage arising from the remnant polarization in ferroelectric layer 120 and any charge on electrodes 110 and 130.

Currently preferred ferroelectric materials such as Lead Zirconate Titanate (i.e., Pb(ZrₓTi₁₋ₓ)O₃ or PZT) commonly contain a substantial amount of active oxygen that can react with the surrounding materials during integrated circuit manufacturing processes. Accordingly, the electrodes in ferroelectric capacitors are commonly made of an oxidation resistant metal, e.g., precious metal such as platinum (Pt), palladium (Pd), ruthenium (Ru), or iridium (Ir).

In the illustrated example of FIG. 1, FeRAM cell 100 uses PZT in ferroelectric layer 120 and iridium in electrodes 110 and 130. More particularly, top electrode 110 includes an iridium layer 112 and an iridium oxide (IrOx) layer 114 adjacent PZT layer 120. Similarly, bottom electrode 120 includes an iridium layer 132 and an iridium oxide layer 134 adjacent PZT layer 120. Typically, a barrier metal layer 136 is between Ir layer 132 and substrate 140 to improve bonding and prevent Ir from layer 132 from diffusing into or otherwise interacting with substrate 140.

Fabrication of FeRAM cells such as FeRAM cell 100 generally involves forming unpatterned layers of precious metal such as Ir and ferroelectric material such as PZT and then patterning the layers to form separate FeRAM cells. Fabricating devices with high memory densities, for example, where each FeRAM cell is less than a micron in critical dimension, requires precise etch processes for patterning the electrode and ferroelectric layers.

Reactive ion etching (RIE) or plasma etching is often chosen for processes requiring accurate etching of small features. For FeRAM, the etching process needs to create and retain suitable sidewall profiles after etching through a series of different materials. Additionally, a minimal number of masks and minimal processing parameter changes between etching electrode and ferroelectric layer can simplify the manufacturing process and provide higher throughput. In view of these requirements or goals, efficient etch processes for manufacturing FeRAM cells are sought.

### SUMMARY

In accordance with an aspect of the invention, a fabrication process for a ferroelectric capacitor uses the same hard mask containing a material such as titanium (Ti), titanium nitride (TiN), titanium oxide (TiO), or titanium aluminum nitride (TiAlN) for etching iridium and PZT layers. Both Ir and PZT are plasma etched at high substrate temperature (e.g., 350° C.) using Cl₂/O₂-based chemistry. The process adds CHF₃ or other fluorine-containing gas to the Cl₂/O₂-based chemistry for PZT etching and adds N₂ to the Cl₂/O₂-based chemistry for Ir etching. Similarities in the etch process for Ir and PZT permit high throughput device fabrication.

One specific embodiment of the invention is a process performed on a structure including a substrate, an electrode layer containing a material such as iridium, and a ferroelectric layer containing a ferroelectric material such as PZT. The process includes: forming a hard mask containing a material such as titanium; etching the electrode layer in a first plasma containing chlorine and oxygen; and etching the ferroelectric layer in a second plasma containing chlorine, oxygen, and a fluorine-containing compound such as CHF₃. The first plasma etches through the electrode layer in areas that the hard mask defines. The second plasma similarly etches through the ferroelectric layer in areas that the hard mask defines. Generally, the ferroelectric layer is sandwiched between electrode layers and both electrode layers are etched using the same chemistry and the same hard mask. Nitrogen or an inert gas can be added to the first plasma to improve the profiles of sidewalls that etching forms. To improve etch rates, the substrate can be heated to a temperature between 250 and 450° C., preferably 350° C., while etching the electrode and ferroelectric layers.

Another embodiment of the invention is a process for patterning a layer of PZT. The process includes: forming a hard mask of a material containing titanium overlying the PZT layer; and etching the PZT layer in a plasma made from chlorine, oxygen, and a fluorine-containing compound such as CHF₃. The plasma etches through the PZT layer in areas that the hard mask defines. A substrate on which the PZT layer resides is heated to a temperature between 250 and 450° C., preferably 350° C., while etching the PZT layer.

### BRIEF DESCRIPTION OF THE DRAWINGS

FIG. 1 is a cross-sectional view of a ferroelectric capacitor.

FIG. 2 is a cross-sectional view of a structure ready for an etch process in accordance with an embodiment of the invention for forming ferroelectric capacitors.

FIG. 3 is a cross-sectional view of a ferroelectric capacitor formed by a process in accordance with an embodiment of the invention.

FIG. 4 is a block diagram illustrating etching equipment used in a process in accordance with an embodiment of the invention.

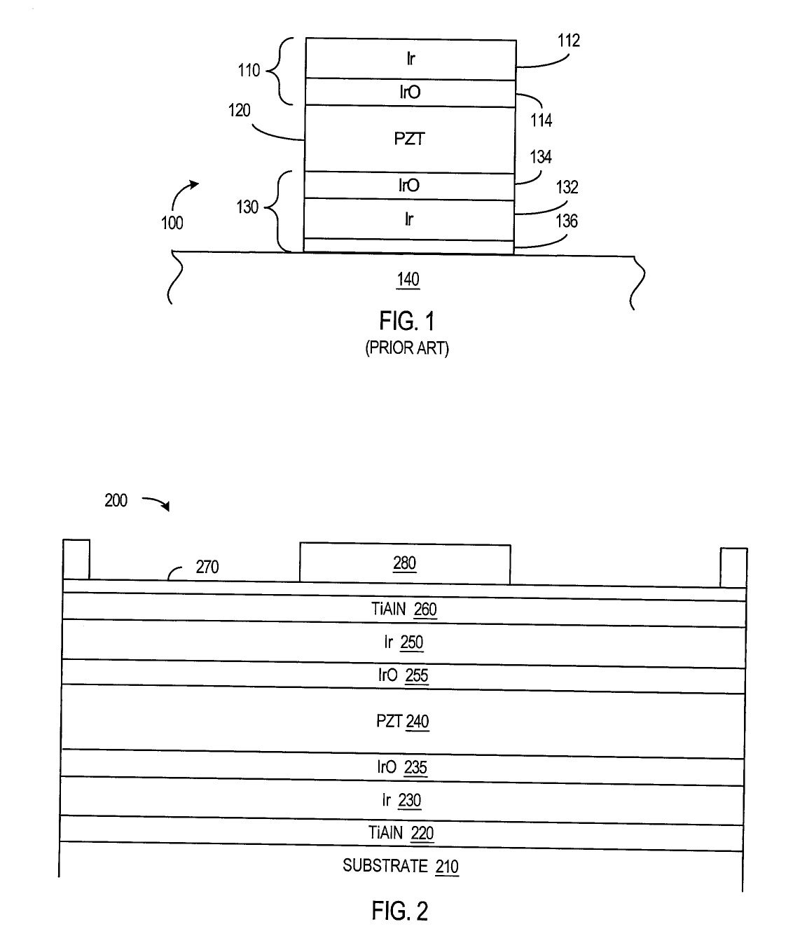

Use of the same reference symbols in different figures indicates similar or identical items.

### DETAILED DESCRIPTION

A fabrication process uses a titanium-containing hard mask, a chlorine/oxygen-based plasma, and a hot substrate for etching of iridium and PZT layers to form separate FeRAM cells or ferroelectric capacitors. The etch process adds a fluorine-containing compound such as CHF₃ to the chlorine/oxygen-based plasma for etching of the PZT layer and adds nitrogen to the chlorine/oxygen-based plasma when etching Ir layers. The chlorine/oxygen-based plasma provides good selectivity with high etch rates for Ir and PZT layer and low etch rates for the hard mask. The resulting ferroelectric capacitors can achieve sub-micro critical dimensions and nearly vertical sidewalls (e.g., sidewall angles greater than about 80°).

FIG. 2 illustrates a structure 200 including a substrate 210 and multiple deposited layers from which an etch process in accordance with the invention can form ferroelectric capacitors. In a typical embodiment, substrate 210 is a processed silicon wafer containing circuit elements (not shown) that will electrically connect to the ferroelectric capacitors through openings in an insulating oxide layer on substrate 210. A series of conventional processes such as chemical vapor deposition (CVD) and sputtering sequentially deposit a barrier layer 220, bottom electrode layers 230 and 235, a ferroelectric layer 240, top electrode layers 250 and 255, and a hard mask layer 260 on substrate 210.

Barrier layer 220 reduces or prevents diffusion or reactions of overlying layers such as electrode layer 230 with substrate 210. Barrier layer 220 also improves bonding or adhesion between substrate 210 and the overlying layers. Suitable materials for barrier layer 220 include but are not limited to Ti, TiN, TiO, or TiAlN, which can be deposited using conventional techniques.

In the illustrated embodiment, the electrodes of the ferroelectric capacitor are formed from iridium layers 230 and 250 and iridium oxide layers 235 and 255, which can be deposited using conventional techniques. For example, sputtering using ions of an inert gas such as argon and an iridium target can form iridium layer 230 on barrier layer 220 or iridium layer 250 on iridium oxide layer 255. Sputtering using oxygen ions and an iridium target can form iridium oxide layers 235 on iridium layer 230 or from iridium oxide layer 255 on ferroelectric layer 240. Iridium oxide layers 235 and 255 are optional but may improve device stability by reducing interactions of the electrodes with active oxygen from ferroelectric layer 240.

In the embodiment of FIG. 2, ferroelectric layer 240 is made of PZT that can be deposited on iridium oxide layer 235 using conventional techniques.

Hard mask layer 260 overlies iridium layer 250 and doubles as a barrier layer for layers and structures (not shown) that may be fabricated overlying layer 260. Accordingly, hard mask layer 260 can be made of the same material as barrier layer 220 so that the same equipment and chemistry that creates a hard mask from hard mask layer 260 can pattern barrier layer 220. In the exemplary embodiment, hard mask layer 250 and barrier layer 220 are TiAlN layers.

In accordance with an aspect of the invention, patterning of hard mask layer 260 creates a hard mask that defines the portions of layers 250, 240, and 230 that are removed to form ferroelectric capacitors. For hard mask creation, a conventional photolithographic process forms a photoresist mask 280 overlying hard mask layer 260. In the embodiment of FIG. 2, photoresist mask 280 has features of sub-micron size, and the photolithographic process uses a bottom anti-reflective coating (BARC) 270 to reduce reflections during exposure of the photoresist and thereby improve the precision of patterning. After the photolithographic exposure, the photoresist is developed to leave mask 280.

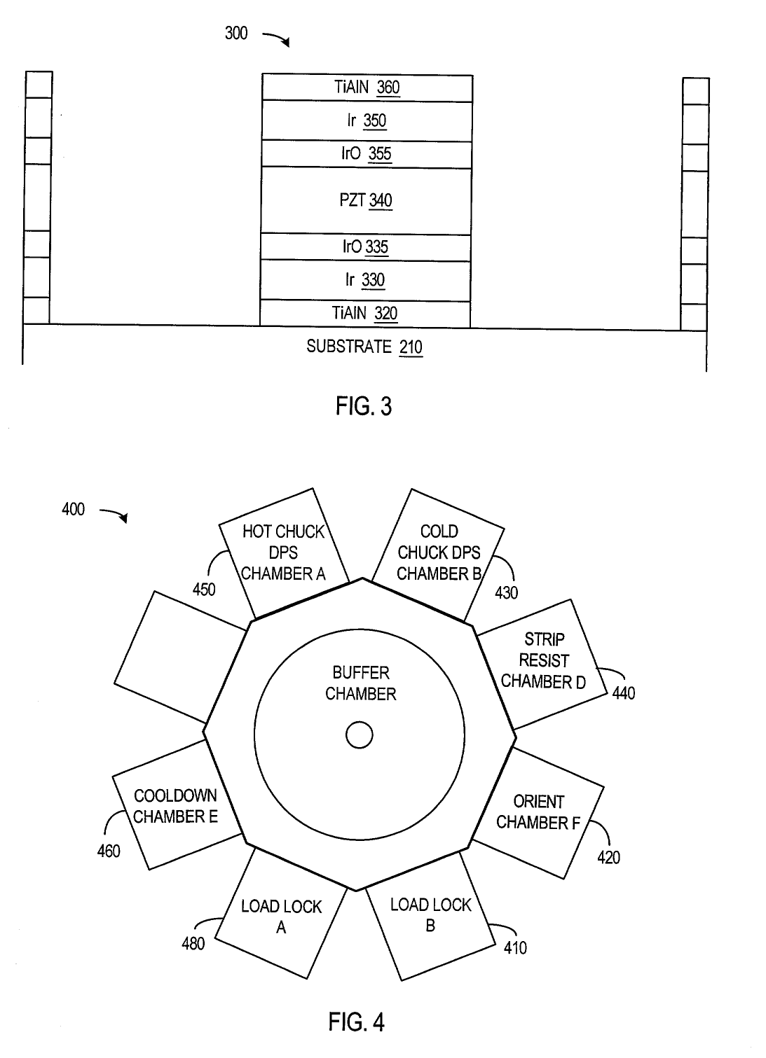

Plasma etching equipment such as the DPS HT Centura or Centura II system available from Applied Materials, Inc. further processes structure 200 of FIG. 2 to first form a hard mask and then to etch through Ir and PZT when forming separate ferroelectric capacitors. FIG. 3 is a cross-sectional view of a ferroelectric capacitor 300 formed from the structure of FIG. 2.

FIG. 4 is a block diagram illustrating equipment 400 used in an etching process that forms ferroelectric capacitor 300 form structure 200. System 400 includes load lock stations 410 and 470 for loading and unloading of wafers, an orientation station 420 that position wafers correctly for mounting on chucks in the reaction chambers, a decoupled plasma source (DPS) reaction chamber 430 having a cold chuck for cold substrate etching, a photoresist stripping station 440, a DPS reaction chamber 450 having a hot chuck for hot substrate etching, and a cooldown station 460. Stations 410 to 480 appear in FIG. 4 in an exemplary order according to etching process described below, but as will be understood by those skilled in the art the number, order, and functions of the stations or equipment used can be combined or varied widely and still perform an etch process in keeping with the present invention.

In an exemplary etch process using equipment 400, load lock 410 loads a wafer including structure 200 of FIG. 2 and transfers the loaded wafer to station 420 for alignment and orientation. The alignment and orientation process positions that wafer for mounting on chucks in other reaction chambers and consistently orients the wafer so that subsequent measurements of the wafers can identify any areas that were consistently subject non-uniform etching. The wafer including structure 200 is then mounted on a cold chuck in DPS reaction chamber 430 for etching.

The etching of structure 200 of FIG. 2 begins with removing portions of BARC 270 that photoresist mask 280 exposes. In the exemplary embodiment of the invention, BARC 270 is an organic compound, which can be removed using plasma containing chlorine and oxygen in a cold (e.g., 15 to 80° C.) substrate process. Other etch processes and chemistries and can remove BARC 270, and the etch process selected generally depend on the specific type of BARC employed.

After removal of the exposed portions of BARC 270, etching openings in hard mask layer 260 (FIG. 2) forms hard mask 360 (FIG. 3). In the exemplary embodiment, hard mask 360 is made of TiAlN, which can be effectively etched using plasma made from a mixture of Cl₂ and BCl₃ in a cold substrate process or any other suitable etch process for etching TiAlN. An advantage of the cold substrate etch processes described here for BARC 270 and hard mask layer 260 is that the removal of BARC 270 and opening of the hard mask can be performed in the same DPS reaction chamber 430 using the same substrate temperature, e.g., 60° C.

After etching in reaction chamber 420 forms hard mask 360, the wafer is moved to station 440 where photoresist mask 280 and remaining portions of BARC 270 can be stripped from the structure using conventional techniques. Stripping the photoresist leaves hard mask 360 overlying layers 250 to 220. The wafer is then moved to reaction chamber 450.

DPS reaction chamber 450 is set up for a hot chuck etching process using a chlorine/oxygen-based plasma chemistry to remove portions of top electrode layers 250 and 255, ferroelectric layer 240, and bottom electrode layers 235 and 230. The hot chuck heats substrate 210 to a temperature above between about 250 and 450° C., and preferably to a temperature of about 350° C.

For etching iridium and iridium oxide layers, nitrogen is introduced into a flow of chlorine and oxygen into plasma chamber 450. Interaction of oxygen with TiAlN in the hard mask 360 is believed to form a protective layer on hard mask 360 that improves selectivity for etching the iridium in electrode layers 250 and 255. Nitrogen in the plasma is found to improve the profile of the sidewalls the etch process forms on iridium and iridium oxide electrode regions 350 and 355. Adding an inert gas such as krypton or argon can improve sidewall profiles, but adding nitrogen in this process generally provides sidewall profiles that are superior to those achieved using an inert gas.

After etching through the top electrode layers, a flow of a fluorine-containing compound such as CHF₃, CF₄, or SF₆ is begun for etching of the PZT layer 240. In particular, CHF₃ provides good selectivity to hard mask 360 and a good sidewall profile for a PZT region 340 formed during the etch process.

After etching through PZT layer 250, the process resumes the nitrogen flow to replace the fluorine-containing compound and etches bottom electrode layers 235 and 230 using the same chemistry as used for the top electrode layers 250 and 255. The resulting bottom electrode contains regions 330 and 335 as shown in FIG. 3.

After the hot chuck etch process etches the exposed portions of the wafer (i.e., layers 235 and 230) down to barrier layer 220, the wafer is transferred back to DPS chamber 430 for a final cold chuck etch process. The final etch operation is a cold substrate plasma etch process that removes exposed portions of barrier layer 220 (FIG. 2) to leave barrier regions 320 (FIG. 3). FIG. 4 illustrates use of the same reaction chamber 430 for etching hard mask layer 260 and barrier layer 220 because the etching of barrier layer 220 is substantially the same as the etching of hard mask layer 260. Alternatively, etching of barrier layer 220 can be conducted in a separate reaction chamber using the process described above or a different process according to the composition of respective layers.

After this etching operation, the wafer, having the structure of FIG. 3, is transferred to cooldown chamber 460 and then to load lock 410 for unloading.

Table 1 shows etch parameters for an exemplary etch process that can be conducted in the Centura II plasma etching equipment for etching BARC layer 270, TiAlN layers 220 and 260, Ir/IrOx layers 230/235 and 250/255; and PZT layer 240, when those layers have the thicknesses indicated in Table 1. In Table 1, the power settings X/Y indicate X watts of the RF power in the coil inductor and Y watts of RF power through the pedestal. The RF frequency for both the coil inductor and the pedestal is generally between about 100 KHz and 300 MHz.

TABLE 1
Exemplary Etch Parameters

| Layer | Power | Pressure | Flow | Temp. | Time |
|---|---|---|---|---|---|
| Layer | (W) | (mTorr) | (sccm) | (° C.) | (s) |
| BALRC (60 nm) | 300/50 | 3 | 40Cl2/20O2 | 60 | 25 |
| TiAlN (200 nm) | 1400/100 | 5 | 110Cl2/20BCl3 | 60 | 65 |
| Ir/IrOx (100 nm) | 1200/450 | 10 | 140Cl2/45O2/18N2 | 350 | 82 |
| PZT (80 nm) | 1200/450 | 10 | 140Cl2/45O2/12CHF3 | 350 | 80 |

The exemplary etch parameters of Table 1 when applied to structure 200 of FIG. 2 provide an etch rate of more than 85 nm/min for removal of Ir or IrOx and an etch rate greater than 100 nm/min for removal of PZT. The etch rate for hard mask 360 during removal of Ir, IrOx, and PZT is more than a factor of 20 lower. Additionally, the etch processes achieve Ir and PZT sidewall slopes that are greater than 82°.

Although the invention has been described with reference to particular embodiments, the description is only an example of the invention's application and should not be taken as a limitation. Various adaptations and combinations of features of the embodiments disclosed are within the scope of the invention as defined by the following claims.

What is claimed is:

1. A process for fabricating a ferroelectric capacitor:
forming a structure including an electrode layer and a ferroelectric layer on a substrate;
forming a hard mask overlying the electrode layer and the ferroelectric layer;
etching the electrode layer in a first plasma containing chlorine and oxygen, wherein the first plasma etches through the electrode layer in areas that the hard mask defines; and
etching the ferroelectric layer in a second plasma containing chlorine, oxygen, and a fluorine-containing compound, wherein the second plasma etches through the ferroelectric layer in areas that the hard mask defines.

2. The method of claim 1, wherein the first plasma further comprises nitrogen.

3. The process of claim 1, wherein the electrode layer comprises iridium.

4. The process of claim 1, wherein the fluorine-containing compound comprises CHF₃.

5. The process of claim 1, wherein the ferroelectric layer comprises PZT.

6. The process of claim 1, wherein the hard mask comprises a material selected from the group consisting of titanium, titanium oxide, titanium nitride, and titanium aluminum nitride.

7. The process of claim 6, wherein the hard mask comprises titanium aluminum nitride.

8. The process of claim 1, further comprising maintaining the substrate at a temperature between 250 and 450° C. while etching the electrode layer and the ferroelectric layer.

9. The process of claim 1, wherein:
the electrode layer overlies the ferroelectric layer and etching of the ferroelectric layer occurs through openings etched through the electrode layer;
the structure further comprises a second electrode layer underlying the ferroelectric layer; and
after etching through the ferroelectric layer, the process further comprises etching the second electrode layer in a third plasma containing chlorine and oxygen, wherein the third plasma etches through the bottom electrode layer in areas that the hard mask defines.

10. The method of claim 9, wherein the second electrode layer comprises iridium.

11. A process for patterning a PZT layer, the process comprising:
forming a hard mask of a material containing titanium overlying the PZT layer; and
etching the PZT layer in a plasma of a mixture that contains chlorine, oxygen, and a fluorine-containing compound, wherein the plasma etches through the PZT layer in areas that the hard mask defines.

12. The process of claim 11, wherein the fluorine-containing compound comprises CHF₃.

13. The process of claim 11, further comprising maintaining a substrate on which the PZT layer resides at a temperature between 250 and 450° C. while etching the PZT layer.
